(19) United States
(12) Patent Application Publication
(10) Pub. No.: US 2007/0278701 A1
(43) Pub. Date: Dec. 6, 2007

(54) Semiconductor package and method for fabricating the same

(75) Inventors: Cheng-Yi Chang, Taichung Hsien (TW); Chien-Ping Huang, Hsinchu Hsien (TW); Chih-Ming Huang, Hsinchu Hsien (TW); Chieh-Yuan Lin, Taichung Hsien (TW); Cheng-Hsu Hsiao, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/591,800

(22) Filed: Nov. 1, 2006

(30) Foreign Application Priority Data
Jun. 2, 2006 (TW) 095119549

(51) Int. Cl. H01L 23/28

(52) U.S. Cl. 257/787

(57) ABSTRACT

A semiconductor package and a method for fabricating the same are disclosed. The method includes installing a plurality of conductive components on a plurality of chip carriers of a chip carrier module, connecting electrically the conductive components to electrical connection points of the adjacent chip carriers, mounting and electrically connecting a semiconductor chip to each of the chip carries, forming an encapsulant for enveloping the semiconductor chip and the conductive components, cutting the chip carriers to separate the conductive components installed thereon, exposing a portion of the conductive components out of the encapsulant, forming on the exposed portion of the conductive components an electroplated layer of nickel/gold, and separating the chip carriers from each other. The conductive components exposed out of the encapsulant provide extra electrical connection points and thereby promote the functionalities of electronic products.

### BACKGROUND OF THE INVENTION

1. Field of the Invention

The present invention relates to a semiconductor package and a method for fabricating the same and, more particularly, to a semiconductor package with a plurality of extra electrical connection points and a method for fabricating the same.

2. Description of the Prior Art

With the demand for portable communication, network and computer products increasing greatly, the trend of the package market is toward ball grid array (BGA) packages. The fabrication of thin fine-pitch ball grid array (TFBGA) packages and land grid array (LGA) packages involves defining a plurality of package units disposed in an array, die bonding, wire bonding, encapsulation, and singulation, as disclosed in U.S. Pat. Nos. 5,776,798, 6,593,658 and 6,281,047.

The fabrication process of quad flat no-lead (QFN) packages also involves disposing leadframes which function as chip carriers in an array, wire bonding, encapsulation and cutting, as disclosed in U.S. Pat. Nos. 6,143,981, 6,399,415 and 6,424,024.

Taiwanese Patent No. I242820, entitled “Sensing Semiconductor Device and Method for Fabricating the Same”, discloses integrating both a control chip and a sensing chip into a package with a view to building a compact camera module (CCM) package, using, basically, a thin fine-pitch ball grid array (TFBGA) package.

Nevertheless, as regards TFBGA, LGA and CCM, electrical connection points for electrical connection with the outside are typically accessed from the bottom, rather than the side, of a semiconductor package or a carrier thereof, not to mention that the electrical connection points cannot be disposed on the top (of an encapsulant). As a result, electrical functions of electronic products are not optimized, and use of electronic products is not widened to the full; for instance, with the prior art, it is not feasible to build up packages, nor is it possible to electrically connect a package to an external device by means of a socket.

Accordingly, an issue that needs urgent solution involves providing a plurality of extra electrical connection points for eliminating restrictions imposed on use of electronic products and enhancing electrical functions of electronic products.

### SUMMARY OF THE INVENTION

In light of the aforesaid drawbacks of the prior art, it is a primary objective of the present invention to provide a semiconductor package having a plurality of extra electrical connection points and a method for fabricating the same with a view to enhancing electrical functions of electronic products and widening use thereof.

Another objective of the present invention to provide a semiconductor package and a method for fabricating the same with a view to forming electrical connection points on a lateral surface of the semiconductor package.

Yet another objective of the present invention to provide a semiconductor package and a method for fabricating the same with a view to forming electrical connection points on a lateral surface and a top surface of the semiconductor package.

A further objective of the present invention to provide a semiconductor package and a method for fabricating the same so as to enable direct electrical stacking of semiconductor packages.

A further objective of the present invention to provide a semiconductor package and a method for fabricating the same so as to enable electrical connection with a socket.

In order to achieve the above and other objectives, the present invention provides a method for fabricating a semiconductor package. The method comprises the steps of providing a chip carrier module having a plurality of chip carriers, the chip carriers each having a plurality of electrical connection points disposed thereon, disposing on the chip carrier module conductive components corresponding in position to the chip carriers, connecting electrically the conductive components to the electrical connection points of the adjoining chip carriers, mounting and electrically connecting a semiconductor chip to each of the chip carriers, forming an encapsulant on the chip carrier module and configured to envelop the semiconductor chip and the conductive components, cutting the encapsulant and the conductive components between the chip carriers, separating the conductive components disposed on the adjoining chip carriers, exposing a portion of the conductive components out of the encapsulant, forming a metal layer of nickel/gold on the conductive components exposed out of the encapsulant so as to enhance the quality of electrical connection with the outside, and separating the chip carriers from each other.

Afterward the method further comprises the steps of exposing otherwise an upper surface of the conductive components out of the encapsulant directly after the molding process, or, alternatively, thinning out the encapsulant so as to expose the upper surface of the conductive components out of the encapsulant, then cutting the encapsulant and the conductive components so as to expose a lateral surface of the conductive components out of the encapsulant, thus using an exposed upper surface and the exposed lateral surface of the conductive components as electrical connection points for electrical connection with the outside.

With the aforesaid method, the present invention also discloses a semiconductor package. The semiconductor package comprises a chip carrier, at least one semiconductor chip, a plurality of conductive components, and an encapsulant. The chip carrier has a plurality of electrical connection points disposed on. The semiconductor chip is mounted and electrically connected to the chip carrier. The conductive components are mounted and electrically connected to the electrical connection points. The encapsulant is formed on the chip carrier and configured to envelop the semiconductor chip and the conductive components so as to allow at least one lateral surface of the conductive components to be exposed out of the encapsulant. An upper surface of the encapsulant is level with an upper surface of the conductive components such that the upper surface of the conductive components is exposed out of the encapsulant.

Accordingly, a semiconductor package and a method for fabricating the same of the present invention comprises the steps of disposing on a chip carrier module having a plurality of chip carriers conductive components corresponding in position to the chip carriers, connecting electrically the conductive components to electrical connection points of the adjoining chip carriers, mounting and electrically connecting a semiconductor chip to each of the chip carriers, performing a molding process to form an encapsulant on the chip carrier module such that the semiconductor chip and the conductive components are enveloped in the encapsulant, cutting the chip carriers from each other, separating the conductive components disposed on the adjoining chip carriers, exposing a portion of the conductive components out of the encapsulant, exposing an upper surface of the conductive components out of the encapsulant directly after the molding process, or, alternatively, thinning out the encapsulant so as to allow the upper surface of the conductive components to be exposed out of the encapsulant, then forming a metal layer of nickel/gold on the conductive components exposed out of the encapsulant so as to enhance the quality of electrical connection with the outside, and separating the chip carriers from each other. Hence, the conductive components exposed out of the encapsulant provide extra electrical connection points to facilitate stacking of semiconductor packages or electrical connection with an external device through a socket. As a result, restrictions otherwise imposed upon use of electronic products are eliminated, and electrical functions of electronic products are enhanced.

### BRIEF DESCRIPTION OF THE DRAWINGS

FIGS. 1A to 1H are schematic views showing the first embodiment of a semiconductor package and a method for fabricating the same in accordance with the present invention;

FIGS. 2A to 2E are schematic views showing the second embodiment of a semiconductor package and a method for fabricating the same in accordance with the present invention;

FIG. 2B′ is a schematic view showing how to remove a portion of an encapsulant by polishing;

FIG. 3 is a schematic view showing a substrate module used in the third embodiment of a semiconductor package and a method for fabricating the same in accordance with the present invention;

FIGS. 4A to 4E are schematic views showing the fourth embodiment of a semiconductor package and a method for fabricating the same in accordance with the present invention; and

FIGS. 5A to 5C are schematic views showing applicable embodiments of a semiconductor package in accordance with the present invention.

### DETAILED DESCRIPTION OF THE PREFERRED EMBODIMENTS

The following specific embodiments are provided to illustrate the present invention. Others skilled in the art can readily gain an insight into other advantages and features of the present invention based on the contents disclosed in this specification.

### First Embodiment

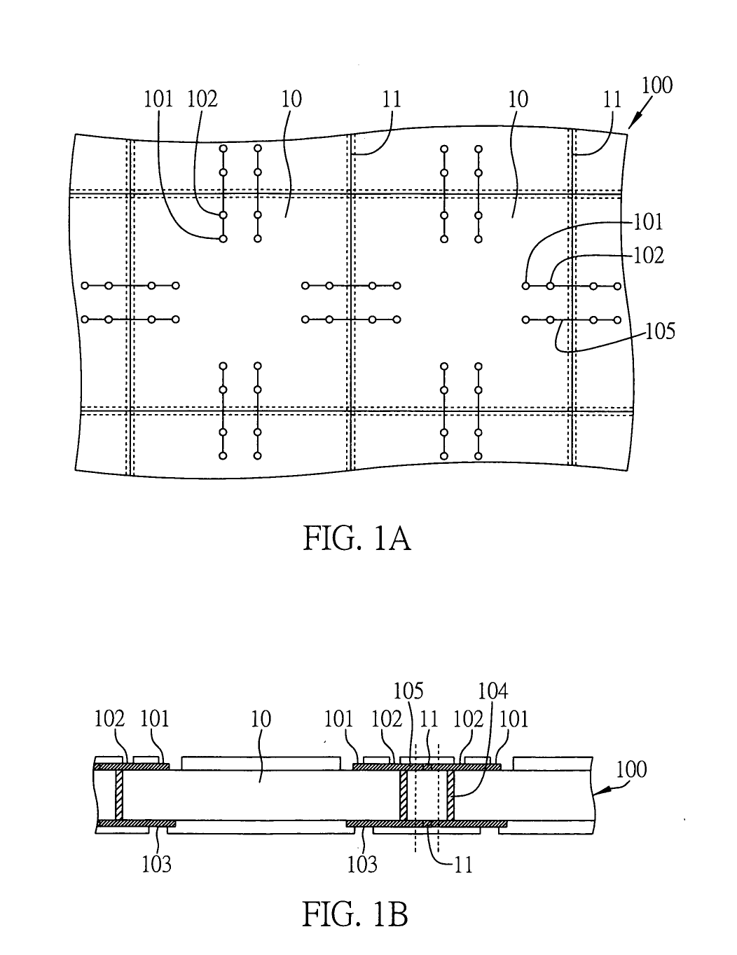

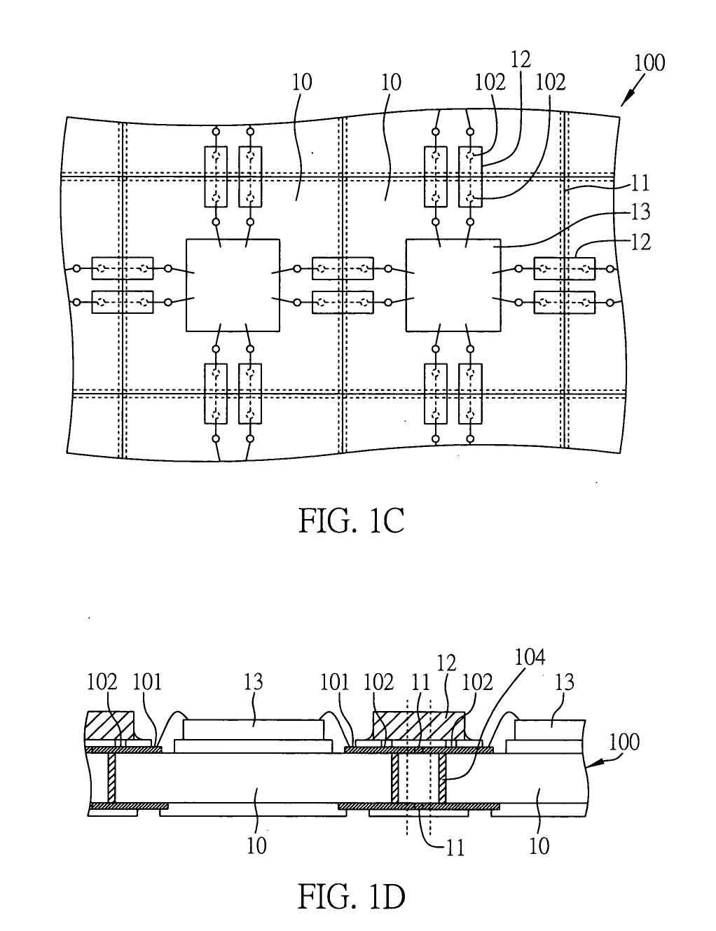

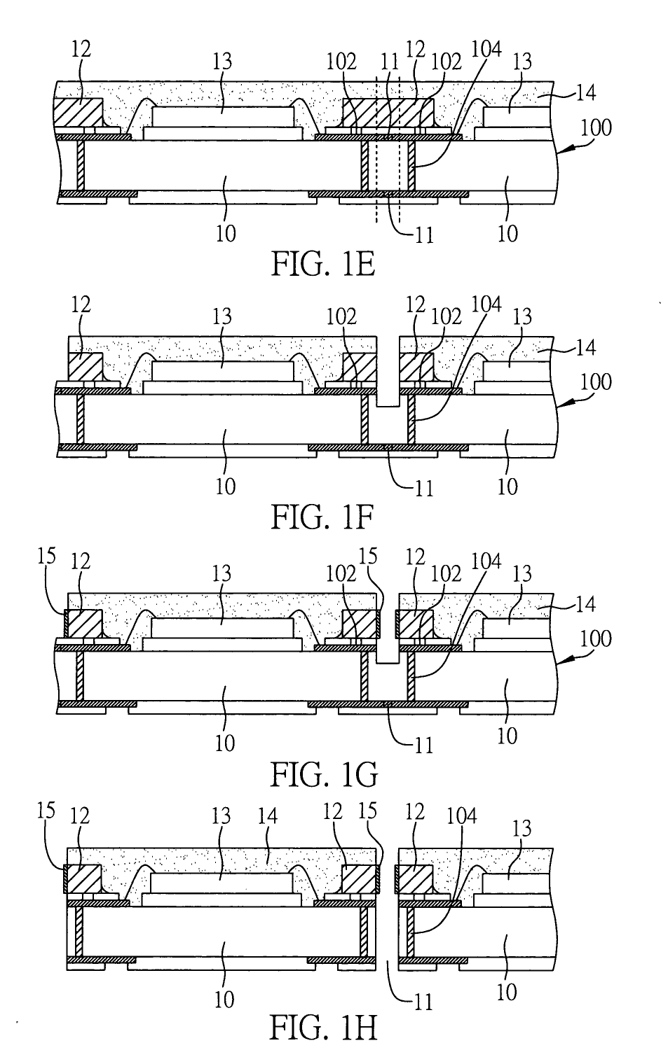

Referring to FIGS. 1A to 1H, which are schematic views showing the first embodiment of a semiconductor package and a method for fabricating the same in accordance with the present invention.

As shown in FIG. 1A, a chip carrier module with a plurality of chip carriers is provided, and the chip carriers each comprise a plurality of electrical connection points. FIG. 1B is a cross-sectional view showing the chip carrier module of FIG. 1A. In this embodiment, the chip carrier module is exemplified by a substrate module 100, and the chip carriers by one of thin fine-pitch ball grid array (TFBGA) substrates 10 and land grid array (LGA) substrates 10. The substrates 10 are demarcated by a plurality of transverse cutting lines and a plurality of longitudinal cutting lines (both indicated by dashed lines). Electroplating buses 11 corresponding in position to the transverse cutting lines and the longitudinal cutting lines are disposed on and under the substrate module 100 such that the electroplating buses 11 are disposed around each of the substrates 10. The electroplating buses 11 are extended and electrically connected to a circuit on the substrates 10. The substrates 10 each have a plurality of first and second electrical connection pads 101 and 102 disposed thereon. The substrates 10 each have a plurality of third electrical connection pads 103 disposed thereunder. The first, second and third electrical connection pads 101, 102 and 103 function as electrical connection points. The first electrical connection pads 101 are electrically connected to the third electrical connection pads 103 through conductive vias 104. The first, second and third electrical connection pads 101, 102 and 103 are electrically connected to the electroplating buses 11 through a wire. The third electrical connection pads 103 are one of ball pads in the event of the thin fine-pitch ball grid array (TFBGA) substrates 10 and electrical connection terminals in the event of land grid array (LGA) substrates 10. The first electrical connection pads 101 include, but are not limited to, bonding fingers, for example. The second electrical connection pads 102 include, but are not limited to, contact pads, for example. The first electrical connection pads 101 can also be bump pads, for example.

As shown in FIG. 1C, the substrate module 100 has disposed thereon conductive components 12 corresponding in position to the substrates 10, and the conductive components 12 are electrically connected to the second electrical connection pads 102 of the adjoining substrates 10; a semiconductor chip 13 is mounted and electrically connected to each of the substrates 10. Referring to FIG. 1D, which is a cross-sectional view corresponding to FIG. 1C, the conductive components 12 are, for example, copper cylinders or copper spheres, so as to be electrically connected to the second electrical connection pads 102 of the adjoining substrates 10 through an electrically conductive material like tin solder, or, alternatively, the conductive components 12 can be solder balls made of tin solder. The semiconductor chip 13 is wire bonded and thereby electrically connected to the first electrical connection pads 101 of the substrates 10. Of course, semiconductor chip 13 may also be flip-chip mounted and electrically connected to the substrates 10. The mounting of the conductive components 12 can be carried out either before or after die mounting.

Referring to FIG. 1E, formed on the substrate module 100 is an encapsulant 14 configured to envelop the semiconductor chip 13 and the conductive components 12.

Referring to FIG. 1F, the encapsulant 14 and the conductive components 12 are cut to separate the substrates 10 from each other and thereby separate the conductive components 12 disposed on the adjoining substrates 10, such that a lateral surface of the conductive components 12 is exposed out of the encapsulant 14. The encapsulant 14 and the conductive components 12 are cut to such a depth that the conductive components 12 at least stay connected electrically to the electroplating buses 11 whereby, during an electroplating process afterward, nickel/gold is deposited on the conductive components 12 exposed out of the encapsulant.

Referring to FIG. 1G, after the cutting and severing of the conductive components 12 on the substrates 10, a remaining portion of the conductive components 12 is still electrically connected to the electroplating buses 11 through the second electrical connection pads 102 and the conductive vias 104, and thus it is feasible to form a metal layer 15 of nickel/gold on the lateral surface of the conductive components 12 exposed out of the encapsulant 14, by electroplating.

Referring to FIG. 1H, the substrates 10 are cut and thereby separated from each other so as to finish fabricating a semiconductor package with an encapsulant comprising a lateral surface with a plurality of extra electrical connection points disposed thereon.

Accordingly, with the aforesaid method, the present invention also discloses a semiconductor package. The semiconductor package comprises a chip carrier, at least one semiconductor chip 13, a plurality of conductive components 12, and an encapsulant 14. The chip carrier is exemplified by a substrate 10. The substrate 10 has disposed thereon a plurality of electrical connection points, such as a plurality of first, second and third electrical connection pads 101, 102 and 103. The semiconductor chip 13 is electrically connected to the substrate 10 by wire bonding or flip-chip connection. The conductive components 12 are mounted and electrically connected to the electrical connection points, such as the second electrical connection pads 102. The encapsulant 14 is formed on the substrate 10 and configured to envelop the semiconductor chip 13 and the conductive components 12 such that at least the lateral surface of the conductive components 12 is exposed out of the encapsulant 14.

### Second Embodiment

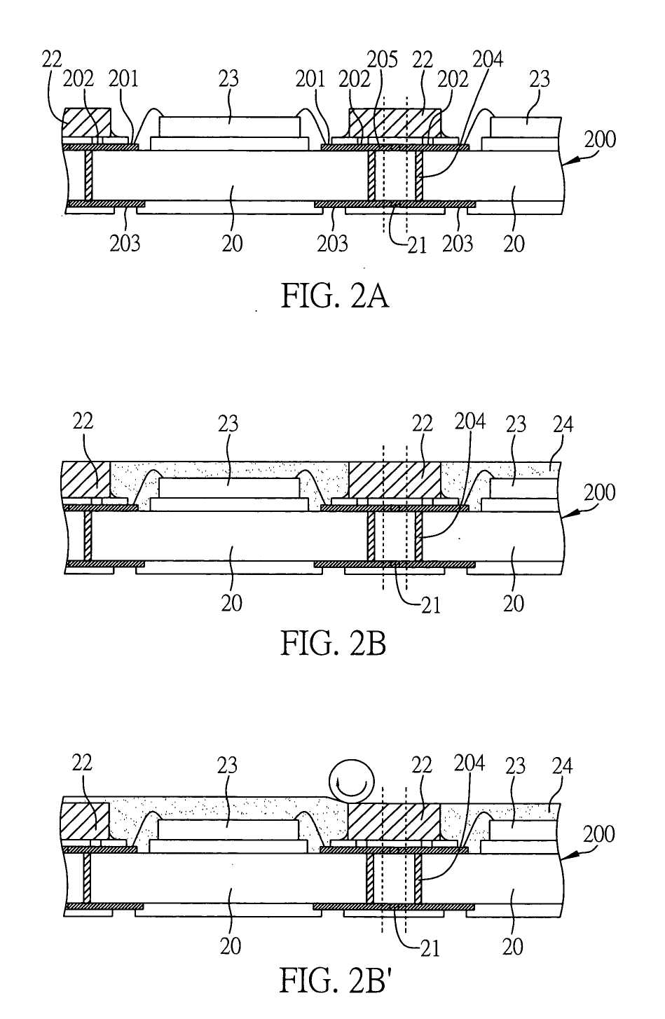

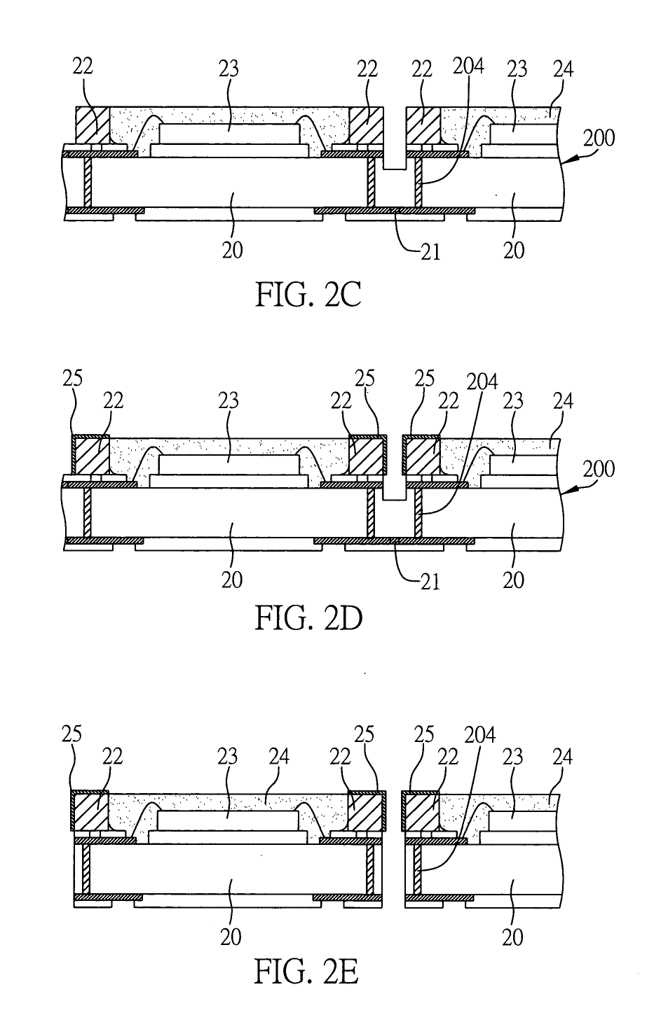

Referring to FIGS. 2A to 2E, which are schematic views showing the second embodiment of a semiconductor package and a method for fabricating the same in accordance with the present invention. Insomuch as this embodiment is mostly similar to its predecessor, its corresponding components are not described in detail and anew, but its distinguishing features are.

Referring to FIG. 2A, a substrate module 200 comprises a plurality of substrates 20 with electroplating buses 21 disposed thereon and thereunder. The electroplating buses 21 are disposed around each of the substrates 20, extended and electrically connected to a circuit on the substrates 20. The substrates 20 each have disposed thereon a plurality of electrical connection points, such as a plurality of first and second electrical connection pads 201 and 202. The substrates 20 each have disposed thereunder a plurality of electrical connection points, such as a plurality of third electrical connection pads 203. The first electrical connection pads 201 are electrically connected to the third electrical connection pads 203 through conductive vias 204. The first, second and third electrical connection pads 201, 202 and 203 are electrically connected to the electroplating buses 21 through a wire.

Afterward, the method comprises the steps of disposing on the substrate module 200 conductive components 22 corresponding in position to the substrates 20, connecting electrically the conductive components 22 to the second electrical connection pads 202 on the adjoining substrates 20, mounting and electrically connecting a semiconductor chip 23 to each of the substrates 20, wherein the semiconductor chip 23 is electrically connected to the substrates by bonding wires.

Referring to FIGS. 2B and 2C, the method further comprises the step of performing a molding process so as to form on the substrate module 200 an encapsulant 24 for enveloping the semiconductor chip 23 and the conductive components 22, wherein the conductive components 22 are higher than the semiconductor chip 23 and the bonding wires thereon such that, during the molding process, the conductive components 22 abut on the top of a cavity of a package mold (not shown), and in consequence an upper surface of the conductive components 22 is directly exposed out of the encapsulant 24 after the molding process. Or, alternatively, as shown in FIG. 2B′, the conductive components 22 do not abut on the top of the cavity of the package mold such that the conductive components 22 are enveloped in the encapsulant 24 which is then thinned out, for example, by polishing. An upper surface of the encapsulant 24 is level with the upper surface of the conductive components 22, and thus the upper surface of the conductive components 22 is exposed out of the encapsulant 24. Then, the method comprises the steps of cutting the encapsulant 24 and the conductive components 22 so as to sever the substrates 20 and thereby separating the conductive components 22 disposed on the adjoining substrates 20, and thus allowing a lateral surface of the conductive components 22 to be exposed out of the encapsulant 24. The encapsulant 24 and the conductive components 22 are cut to such a depth that the conductive components 22 at least stay connected electrically to the electroplating buses 21 whereby, during an electroplating process afterward, nickel/gold is deposited on the conductive components 22 exposed out of the encapsulant 24.

Referring to FIG. 2D, with the electroplating buses 21, a metal layer 25 of nickel/gold is deposited, by electroplating, on the lateral surface and the upper surface of the conductive components 22 exposed out of the encapsulant 24.

Referring to FIG. 2E, the method further comprises the steps of cutting and severing the substrates 20, so as to finish fabricating a semiconductor package with an encapsulant comprising a lateral surface and a top surface both with a plurality of extra electrical connection points disposed thereon.

### Third Embodiment

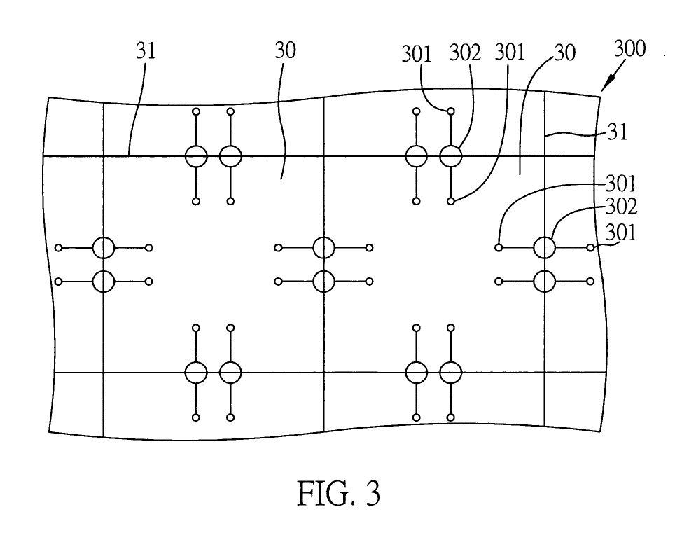

Referring to FIG. 3, which is a schematic view showing a substrate module used in the third embodiment of a semiconductor package and a method for fabricating the same in accordance with the present invention.

As shown in the drawing, this embodiment mainly differs from the preceding embodiment in that, in this embodiment, a substrate module 300 comprises a plurality of substrates 30 with electroplating buses 31 disposed thereon and thereunder. The electroplating buses 31 are disposed around each of the substrates 30. The substrates 30 each have disposed thereon a plurality of electrical connection points, such as a plurality of first and second electrical connection pads 301 and 302. The second electrical connection pads 302 disposed on the adjoining substrates 30 are electrically connected to each other. The first and second electrical connection pads 301 and 302 are electrically connected to the electroplating buses 31.

The ensuing steps of this embodiment are the same as those of the preceding embodiment, namely mounting, electrically connecting the conductive components to the second electrical connection pads of the adjoining substrates, performing die mounting, forming an encapsulant for enveloping the semiconductor chip and the conductive components, cutting the encapsulant and the conductive components so as to sever the substrates, electroplating a metal layer on the conductive components exposed out of the encapsulant, separating the substrates from each other, and thus finishing the fabrication of a semiconductor package with a plurality of extra electrical connection points exposed out of an encapsulant.

### Fourth Embodiment

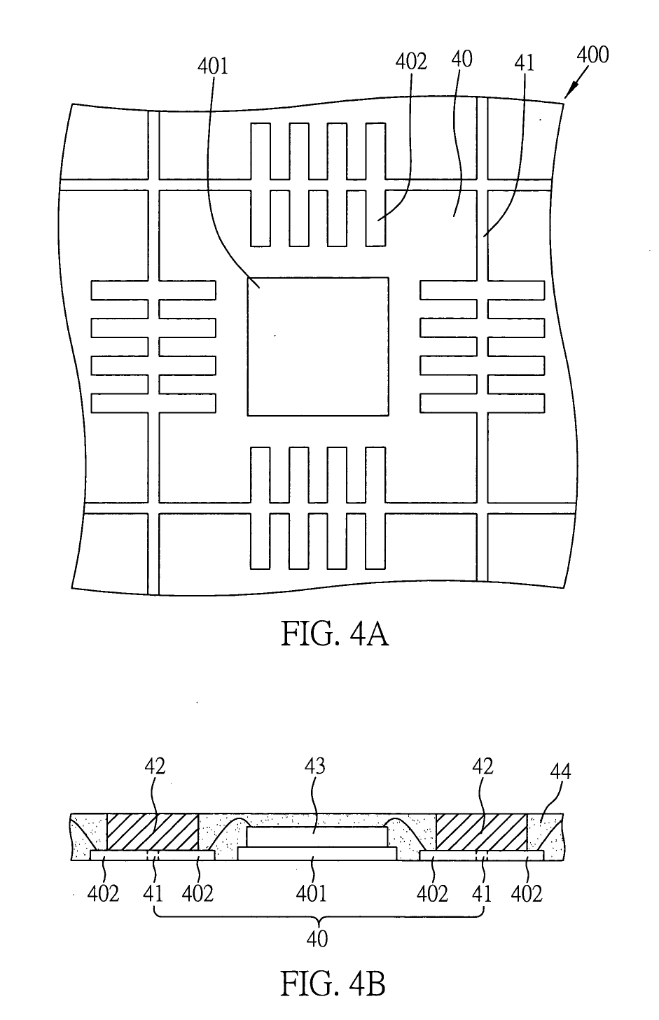

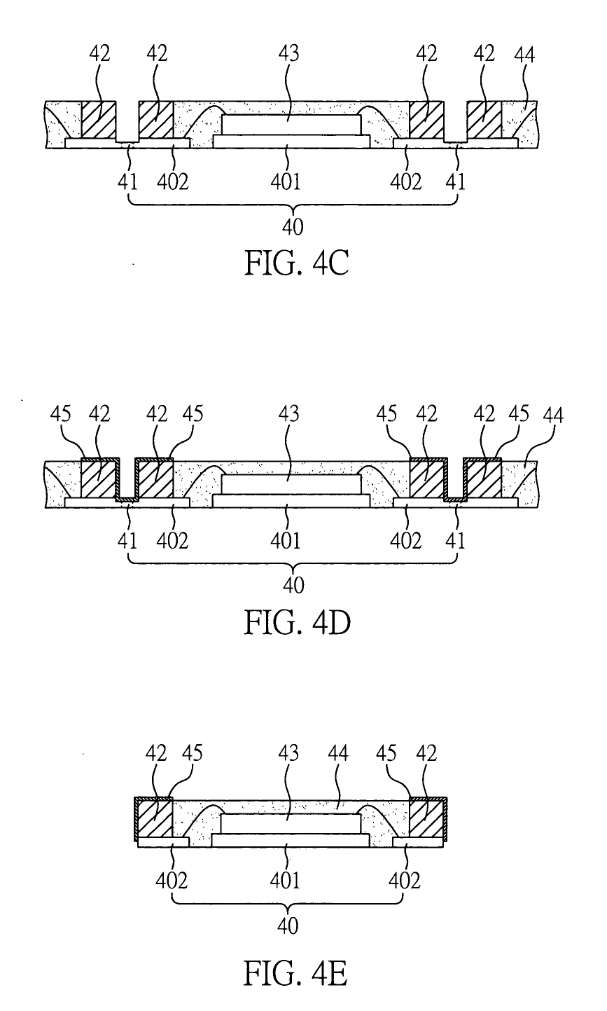

Referring to FIGS. 4A to 4E, which are schematic views showing the fourth embodiment of a semiconductor package and a method for fabricating the same in accordance with the present invention. This embodiment mainly differs from its predecessor in that, in this embodiment, leadframes function as chip carriers.

Referring to FIG. 4A, a leadframe module 400 comprises a plurality of leadframes 40, and each of the leadframes 40 comprises a die pad 401 and a plurality of electrical connection points, such as leads 402, disposed around the die pad 401. The leadframes 40 are, for example, QFN leadframes, and are connected to each other by a connecting bus 41.

Referring to FIG. 4B, the method comprises the steps of disposing on the leadframe module 400 conductive components 42 corresponding in position to the leads 402 of the adjoining leadframes 40, connecting electrically the conductive components 42 to the leads 402 of the adjoining leadframes 40, mounting a semiconductor chip 43 on the die pad 401 of each of the leadframes 40, connecting electrically the semiconductor chip 43 to each of the leads 402 through a plurality of bonding wires, forming on the leadframe module an encapsulant 44 for enveloping the semiconductor chip 43 and the conductive components 42, and allowing an upper surface of the conductive components 42 to be exposed out of the encapsulant 44.

Referring to FIG. 4C, the method further comprises the step of cutting and severing the encapsulant 44 and the conductive components 42 on the adjoining leadframes 40 so as to expose a lateral surface of the conductive components 42 out of the encapsulant 44, wherein the encapsulant 44 and the conductive components 42 are cut to such a depth that the conductive components 42 at least stay connected to the connecting bus 41 electrically.

Referring to FIG. 4D, with the connecting bus 41 for connecting the leads 40 of the leadframes 40, a metal layer 45 of nickel/gold is formed, by electroplating, on the lateral surface and an upper surface of the conductive components 42 exposed out of the encapsulant 44.

Referring to FIG. 4E, the method further comprises the steps of cutting and severing the leadframes 40, so as to finish fabricating a semiconductor package with an encapsulant having a lateral surface and an upper surface with a plurality of extra electrical connection points disposed thereon.

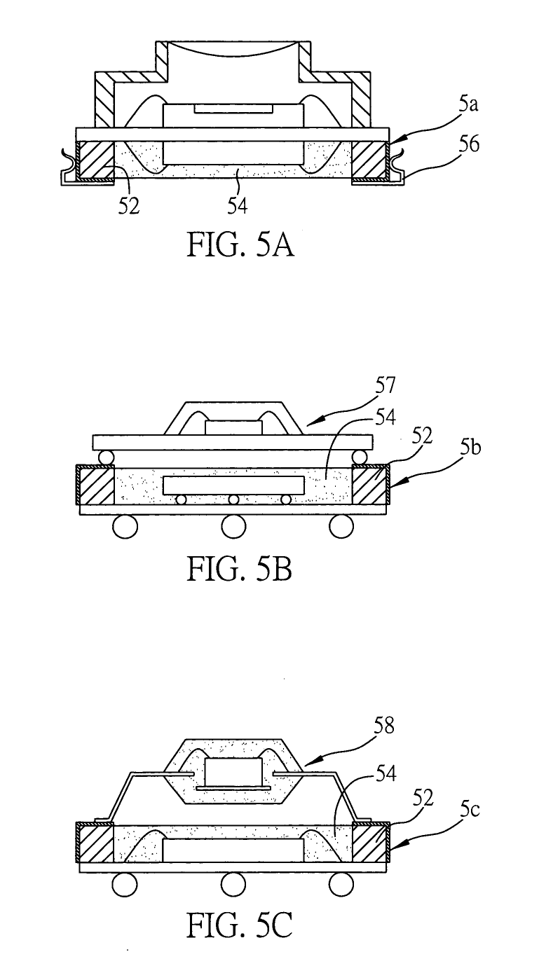

Referring to FIGS. 5A to 5C, which are schematic views showing applicable embodiments of a semiconductor package in accordance with the present invention. As shown in FIG. 5A, as regards a semiconductor package 5a of the present invention, a surface of conductive components 52 exposed out an encapsulant 54 functions as an electrical connection point for electrical connection with a contact terminal 56 of a socket, thus providing a compact camera module (CCM) package to be installed in the socket. Referring to FIGS. 5B and 5C, as regards semiconductor packages 5b and 5c of the present invention, a surface of the conductive components 52 exposed out the encapsulant 54 functions as an electrical connection point for electrically building up second semiconductor packages 57 and 58 on the semiconductor packages 5b and 5c, wherein the second semiconductor packages 57 and 58 are one of ball grid array semiconductor packages (as shown in FIG. 5B) and leadframe semiconductor packages (as shown in FIG. 5C).

Accordingly, a semiconductor package and a method for fabricating the same of the present invention comprises the steps of disposing on a chip carrier module having a plurality of chip carriers conductive components corresponding in position to the chip carriers, connecting electrically the conductive components to electrical connection points of the adjoining chip carriers, mounting and electrically connecting a semiconductor chip to each of the chip carriers, performing a molding process to form an encapsulant on the chip carrier module such that the semiconductor chip and the conductive components are enveloped in the encapsulant, cutting the chip carriers to separate the conductive components disposed on the adjoining chip carriers, exposing a portion of the conductive components out of the encapsulant, separating the chip carriers from each other, exposing an upper surface of the conductive components out of the encapsulant directly after the molding process, or, alternatively, thinning out the encapsulant so as to allow the upper surface of the conductive components to be exposed out of the encapsulant, then forming a metal layer of nickel/gold on the conductive components exposed out of the encapsulant so as to enhance the quality of electrical connection with the outside, and separating the chip carriers from each other. Hence, the conductive components exposed out of the encapsulant provide extra electrical connection points to facilitate stacking of semiconductor packages or electrical connection with an external device through a socket. As a result, restrictions otherwise imposed upon use of electronic products are eliminated, and electrical functions of electronic products are enhanced.

The foregoing specific embodiments are only illustrative of the features and functions of the present invention but are not intended to restrict the scope of the present invention. It is apparent to those skilled in the art that all equivalent modifications and variations made in the forgoing embodiments according to the spirit and principle in the disclosure of the present invention should fall within the scope of the appended claims.

1. A method for fabricating a semiconductor package, the method comprising the steps of:
providing a chip carrier module having a plurality of chip carriers, the chip carriers each having a plurality of electrical connection points disposed thereon;
disposing on the chip carrier module conductive components corresponding in position to the chip carriers, connecting electrically the conductive components to the electrical connection points of the adjoining chip carriers, mounting and electrically connecting a semiconductor chip to each of the chip carriers;
performing a molding process whereby an encapsulant is formed on the chip carrier module and configured to envelop the semiconductor chip and the conductive components; and
cutting the encapsulant and the conductive components between the chip carriers, separating the conductive components disposed on the adjoining chip carriers, exposing a portion of the conductive components out of the encapsulant, and separating the chip carriers from each other.

2. The method of claim 1, further comprising, during a molding process, allowing the conductive components to abut on a top of a cavity of a package mold such that, upon completion of the molding process, an upper surface of the conductive components is exposed out of the encapsulant.

3. The method of claim 1, further comprising enveloping the conductive components in the encapsulant, then thinning out the encapsulant, so as to expose the upper surface of the conductive components.

4. The method of claim 1, further comprising forming a metal layer on the conductive components exposed out of the encapsulant.

5. The method of claim 1, wherein the chip carrier module is a substrate module, and the chip carriers are one of thin fine-pitch ball grid array (TFBGA) substrates and land grid array (LGA) substrates, the substrates being demarcated by a plurality of transverse cutting lines and a plurality of longitudinal cutting lines, the substrates each having electroplating buses disposed thereon and thereunder along the transverse cutting lines and the longitudinal cutting lines such that the electroplating buses are disposed around each of the substrates, the electroplating buses being extended and electrically connected to a circuit on the substrates.

6. The method of claim 5, wherein the substrates have a plurality of first and second electrical connection pads disposed thereon and a plurality of third electrical connection pads disposed thereunder, the first electrical connection pads being electrically connected to the third electrical connection pads through conductive vias, the first, second and third electrical connection pads being electrically connected to the electroplating buses.

7. The method of claim 6, wherein the third electrical connection pads are one of ball pads in the event of the thin fine-pitch ball grid array (TFBGA) substrates and electrical connection terminals in the event of the land grid array (LGA) substrates, the first electrical connection pads are one of bonding fingers and flip-chip pads, the second electrical connection pads are contact pads.

8. The method of claim 6, wherein the conductive components are electrically connected to the second electrical connection pads of the adjoining substrates, and the semiconductor chip is electrically connected to the first electrical connection pads of the substrates.

9. The method of claim 6, wherein the second electrical connection pads of the adjoining substrates are connected to each other.

10. The method of claim 5, wherein the encapsulant and the conductive components are cut to such a depth that the conductive components at least stay connected to the electroplating buses electrically.

11. The method of claim 5, wherein the conductive components are electrically connected to the electroplating buses such that a metal layer is electroplated on the conductive components exposed out of the encapsulant.

12. The method of claim 1, wherein the chip carrier module is a leadframe module, and the chip carriers are leadframes each comprising a die pad and a plurality of leads disposed around the die pad, the leadframes being connected to each other by a connecting bus.

13. The method of claim 12, wherein the die pad of each of the leadframes is mounted with the semiconductor chip electrically connected to the leads through a plurality of bonding wires.

14. The method of claim 12, wherein the leadframe module has disposed thereon the conductive components corresponding in position to the leads of the adjoining leadframes, the conductive components being electrically connected to the leads of the adjoining leadframes.

15. The method of claim 12, wherein the encapsulant and the conductive components are cut to such a depth that the conductive components at least stay connected to the connecting bus electrically.

16. The method of claim 12, wherein the conductive components are electrically connected to the connecting bus connecting the leadframes such that a metal layer is electroplated on the conductive components exposed out of the encapsulant.

17. The method of claim 1, wherein the semiconductor package uses a surface of the conductive components exposed out of the encapsulant as an electrical connection point for connecting to a contact terminal of a socket electrically.

18. The method of claim 2, wherein the semiconductor package uses a surface of the conductive components exposed out of the encapsulant as an electrical connection point for building up another semiconductor package thereon electrically.

19. A semiconductor package, comprising:
a chip carrier having a plurality of electrical connection points disposed thereon;
at least one semiconductor chip mounted and electrically connected to the chip carrier;
a plurality of conductive components mounted and electrically connected to the electrical connection points; and
an encapsulant formed on the chip carrier and configured to envelop the semiconductor chip and the conductive components, the conductive components comprising at least one lateral surface exposed out of the encapsulant.

20. The semiconductor package of claim 19, wherein the encapsulant comprises an upper surface being level with an upper surface of the conductive components such that the upper surface of the conductive components is exposed out of the encapsulant.

21. The semiconductor package of claim 19, further comprising a metal layer formed on the conductive components exposed out of the encapsulant.

22. The semiconductor package of claim 19, wherein the chip carrier is one of a thin fine-pitch ball grid array (TFBGA) substrate and a land grid array (LGA) substrate.

23. The semiconductor package of claim 22, wherein the substrate has a plurality of first and second electrical connection pads disposed thereon and a plurality of third electrical connection pads disposed thereunder, the first electrical connection pads being electrically connected to the third electrical connection pads through conductive vias.

24. The semiconductor package of claim 23, wherein the third electrical connection pads are one of ball pads in the event of the thin fine-pitch ball grid array (TFBGA) substrate or electrical connection terminals in the event of the land grid array (LGA) substrate, the first electrical connection pads being one of bonding fingers and flip-chip pads, the second electrical connection pads being contact pads.

25. The semiconductor package of claim 23, wherein the conductive components are electrically connected to the second electrical connection pads, and the semiconductor chip is electrically connected to the first electrical connection pads.

26. The semiconductor package of claim 19, wherein the chip carrier is a leadframe with a die pad and a plurality of leads disposed around the die pad.

27. The semiconductor package of claim 26, wherein the die pad of the leadframe is mounted with the semiconductor chip electrically connected to the leads through a plurality of bonding wires.

28. The semiconductor package of claim 26, wherein the leads are disposed with and electrically connected to the conductive components thereon.

29. The semiconductor package of claim 19, wherein the semiconductor package uses a surface of the conductive components exposed out of the encapsulant as an electrical connection point for connecting to a contact terminal of a socket electrically.

30. The semiconductor package of claim 20, wherein the semiconductor package uses a surface of the conductive components exposed out of the encapsulant as an electrical connection point for building up another semiconductor package thereon electrically.
